(19) United States
(12) Patent Application Publication
(10) Pub. No.: US 2015/0325445 A1
(43) Pub. Date: Nov. 12, 2015

(54) REDUCED SILICON GOUGING DURING OXIDE SPACER FORMATION

(71) Applicant: GLOBALFOUNDRIES INC., Grand Cayman (KY)

(72) Inventors: Jiehui SHU, Ballston Lake, NY (US); Huang LIU, Mechanicville, NY (US)

(73) Assignee: GLOBALFOUNDRIES INC., Grand Cayman (KY)

(21) Appl. No.: 14/270,995

(22) Filed: May 6, 2014

(51) Int. Cl. H01L 21/28; H01L 21/311; H01L 29/40

(52) U.S. Cl. CPC H01L 21/28238; H01L 29/401; H01L 21/31116

(57) ABSTRACT

An improved method for fabricating a semiconductor device is provided to decrease substrate gouging during oxide spacer formation. The method includes: forming a gate structure on a substrate; depositing an oxide layer along the sidewalls of the gate structure and on the substrate; removing some of the oxide layer to define oxide spacers along sidewalls of the gate structure; and performing an isotropic etch process to remove a residual portion of the oxide layer.

### FIELD OF THE INVENTION

The present invention relates to semiconductor devices and methods of their manufacturing, and more particularly to reducing the substrate gouging that occurs during the process of forming an oxide spacer during fabrication.

### BACKGROUND OF THE INVENTION

Semiconductor device fabrication, such as transistor gate fabrication, typically involves several processing steps of depositing, etching, and removing layers to form the desired stack of gate layers. During each processing step, materials may be, for instance, deposited on, or etched from, a substrate. Because gate and, therefore, transistor performance may be impaired if damage to one layer occurs when another is being etched or removed, it may be desirable to seek to enhance gate performance by modifying the process by which layers are deposited and removed during fabrication.

### BRIEF SUMMARY

The shortcomings of the prior art are overcome, and additional advantages are provided, through the provision, in one aspect, of a method for manufacturing a semiconductor device. The method includes: forming a gate structure on a substrate; depositing an oxide layer along the sidewalls of the gate structure and on the substrate; removing some of the oxide layer to define at least one oxide spacer along at least one sidewall of the gate structure; and performing an isotropic etch process to remove a residual portion of the oxide layer from adjacent the at least one oxide spacer.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A is a cross-sectional view of a semiconductor gate structure at an intermediate stage of a conventional fabrication process;

FIG. 1B is a cross-sectional view of a semiconductor gate structure at an intermediate stage of a conventional fabrication process after deposition of a layer from which a spacer is to be formed;

FIG. 1C is a cross-sectional view of a semiconductor gate structure at an intermediate stage of a conventional fabrication process after a spacer has been substantially defined by an anisotropic main etch step;

FIG. 1D is a cross-sectional view of a semiconductor gate structure at an intermediate stage of a conventional fabrication process after residual material has been removed by an anisotropic over etch step and substrate gouging has occurred;

FIG. 2A is a cross-sectional view of a semiconductor gate structure at an intermediate stage of a fabrication process in accordance with the current invention;

FIG. 2B is a cross-sectional view of a semiconductor gate structure at an intermediate stage of a fabrication process after deposition of a layer from which a spacer is to be formed in accordance with the current invention;

FIG. 2C is a cross-sectional view of a semiconductor gate structure at an intermediate stage of a fabrication process after a spacer has been substantially defined by an anisotropic main etch step in accordance with the current invention; and

FIG. 2D is a cross-sectional view of a semiconductor gate structure at an intermediate stage of a fabrication process after residual material has been removed by an isotropic over etch step in accordance with the current invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which for ease of understanding are not drawn to scale, wherein the same reference numbers used throughout different figures designate the same or similar components.

The present disclosure provides, in part, a process for reducing undesirable current leakage of field-effect transistors (FETs) that can result during FET fabrication. During conventional fabrication of a FET gate, a layer may be conformally deposited over a gate structure on a substrate, including along the sidewalls of the gate structure, as well as atop the gate structure and adjacent to the gate structure along the surface of the substrate. Subsequently, some of that layer may be removed from atop the gate structure and from adjacent the gate structure along the surface of the substrate, while a portion of the layer along the sidewalls of the gate structure is not removed, a process for defining physical contours of a spacer. A spacer may function as a mask or implant barrier to protect or block adjoining and underlying portions of a gate structure and substrate during subsequent fabrication steps, such as during doping uncovered portions of a substrate, depositing additional layers, or removing portions of a gate structure or other layer not covered by the spacer. A spacer may also remain after a gate structure, such as a sacrificial gate structure, has been removed, the position of the remaining spacer at least in part delimiting a region in which a replacement gate structure may be formed during subsequent processing steps.

The process of removing portions of a layer to expose underlying material and to create a spacer can lead to undesirable increase the current leakage of a resulting FET. The undesirable current leakage can result from removing part of the substrate underlying a portion of the layer that is removed to form a spacer. For example, a material forming a layer from which a spacer is created and, therefore, a resulting spacer may be an oxide, and a substrate may be polysilicon. Defining the spacer out of such a layer may involve processes that are not completely selective for the oxide relative to the substrate material, meaning that removal of a portion of the oxide layer by such a process may also undesirably result in removal of part of the underlying substrate, referred to as substrate gouging. Substrate gouging may cause an increase in current leakage in a resulting FET.

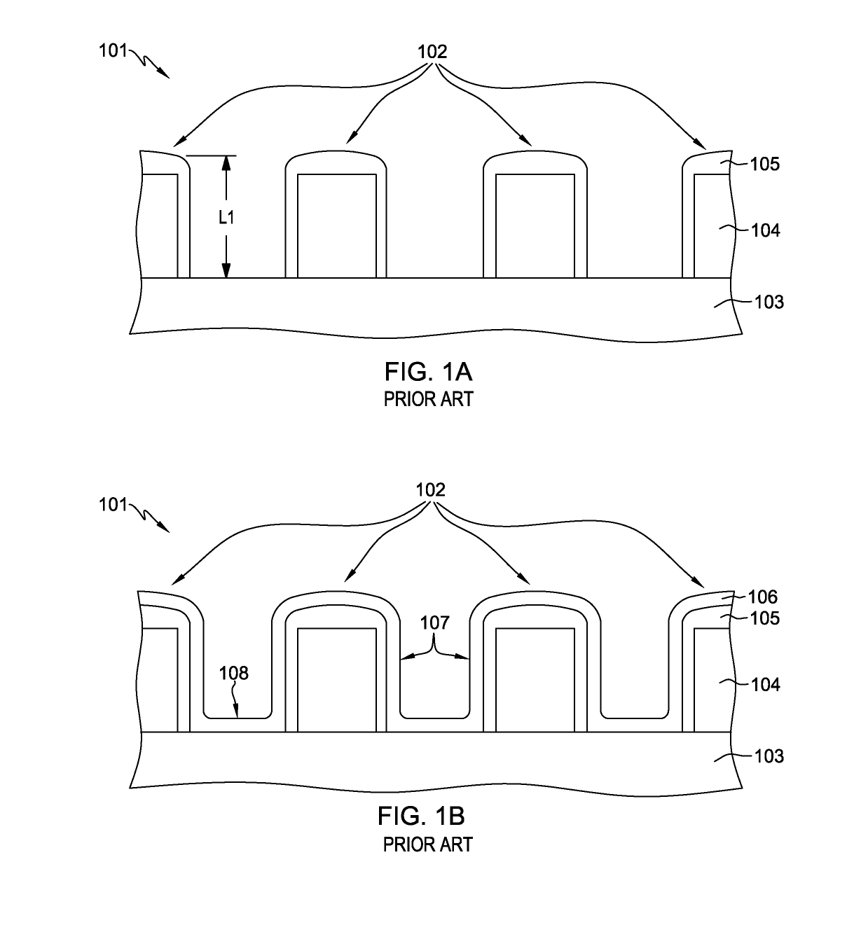

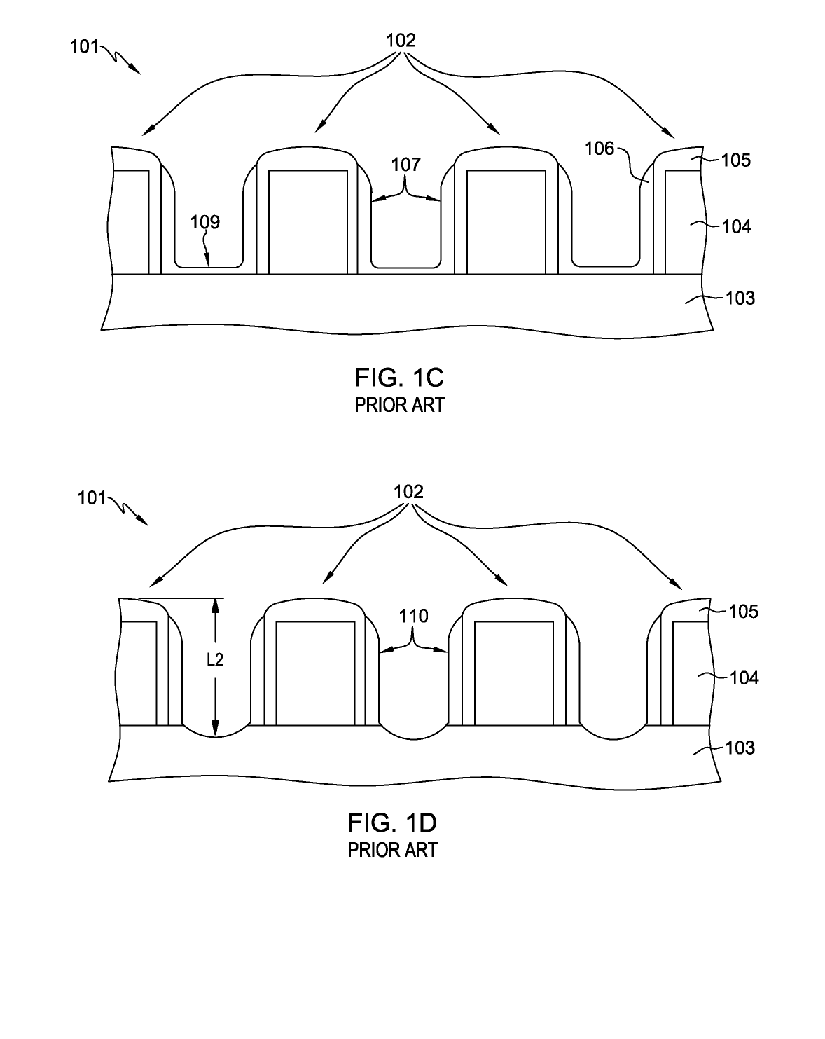

Undesirable substrate gouging is illustrated in FIGS. 1A-1D. FIG. 1A is a partial semiconductor structure 101 during an intermediate fabrication step. Gate structures 102 have been formed on substrate 103. In this example, a gate structure is a gate stack of two layers: a gate material 104 and a protective layer 105. Not shown are other layers that may also be present, such as a layer of dielectric material between the gate material and the substrate. FIG. 1B is the same partial semiconductor substrate 101 after an additional layer 106 has been conformally deposited over the gate structures, including along the sidewalls of the gate structures 107, and adjacent to the gate structures across a surface of the substrate 108.

FIG. 1C is the same partial semiconductor structure 101 after part of additional layer 106 has been removed during a main etch step to define a spacer. Conventionally, a main etch step is an anisotropic etch process used to preferentially remove portions of additional layer 106 from atop gate structures 102 and from adjacent to the gate structures across a surface of the substrate 108, while leaving portions of additional layer 106 along sidewalls of a gate structures 107 to define spacers. After a main etch step, some residual portion 109 of additional layer 106 may remain adjacent to the gate structures across a surface of the substrate, although thinner than that portion was before the main etch step 108.

An over etch step is performed after a main etch step. Conventionally, an over etch step is an anisotropic etch process to remove residual portion 109 adjacent to the gate structures across a surface of the substrate 103. An over etch step may be the same or process as or similar to a main etch step, performed for a duration that is a portion of the duration during which a main etch step was performed. FIG. 1D is the same partial semiconductor substrate 101 after an anisotropic over etch step has been completed. The portions of additional layer 106 that remained along sidewalls of gate structures are now spacers 110. Residual portions 109 (FIG. 1C) of additional layer 106 from adjacent to the gate structures 102 across a surface of the substrate 103 have been removed. However, the anisotropic over etch process is not completely selective for residual portion 109 of additional layer 106 and removes part of substrate 103, causing substrate gouging. As a result of gouging, distance from the top of a gate structure 102 to the surface of substrate 103 before spacer formation, indicated as L1 in FIG. 1A, is shorter than the distance from the top of gate structure 102 to the surface of substrate 103 after the anisotropic over etch step, indicated as L2 in FIG. 1D. The difference between L1 and L2 can be several nanometers, or more, which can be a very significant change with small-scale FETs. This undesirable gouging of substrate 103 impairs the functionality of a resulting FET. For example, gouging may cause an increase in current leakage.

The current invention minimizes substrate gouging by employing a more selective over etch process than conventional methods. In accordance with the current invention, an over etch process is an isotropic etch process. An isotropic etch process can be very selective such that residual material can be removed after an anisotropic main etch step without causing substrate gouging.

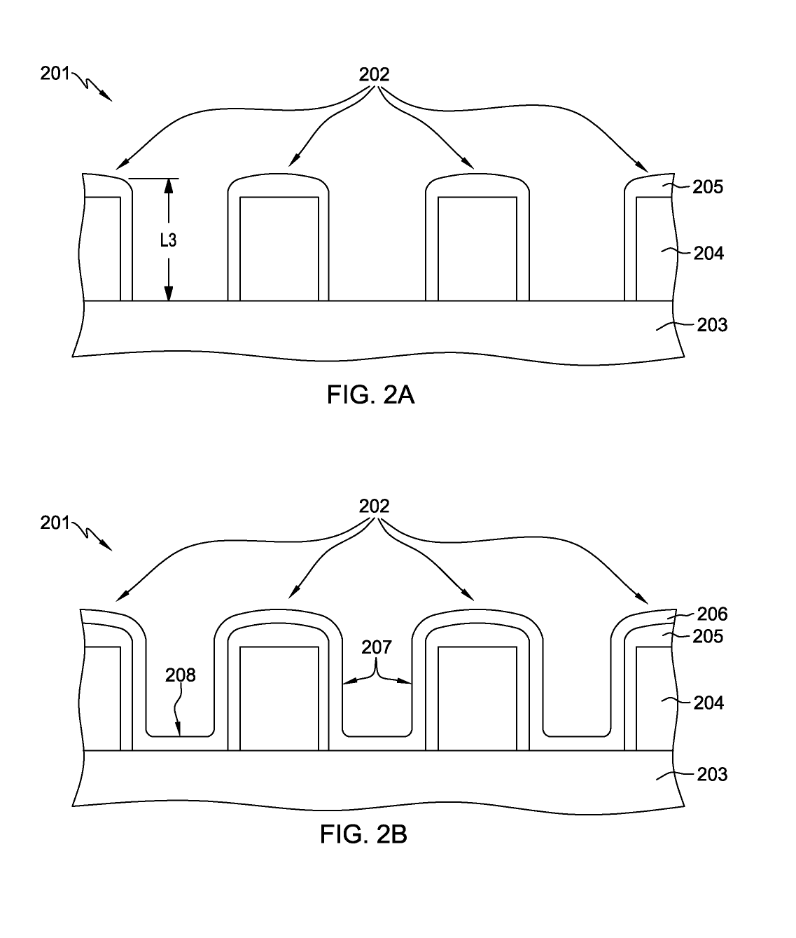

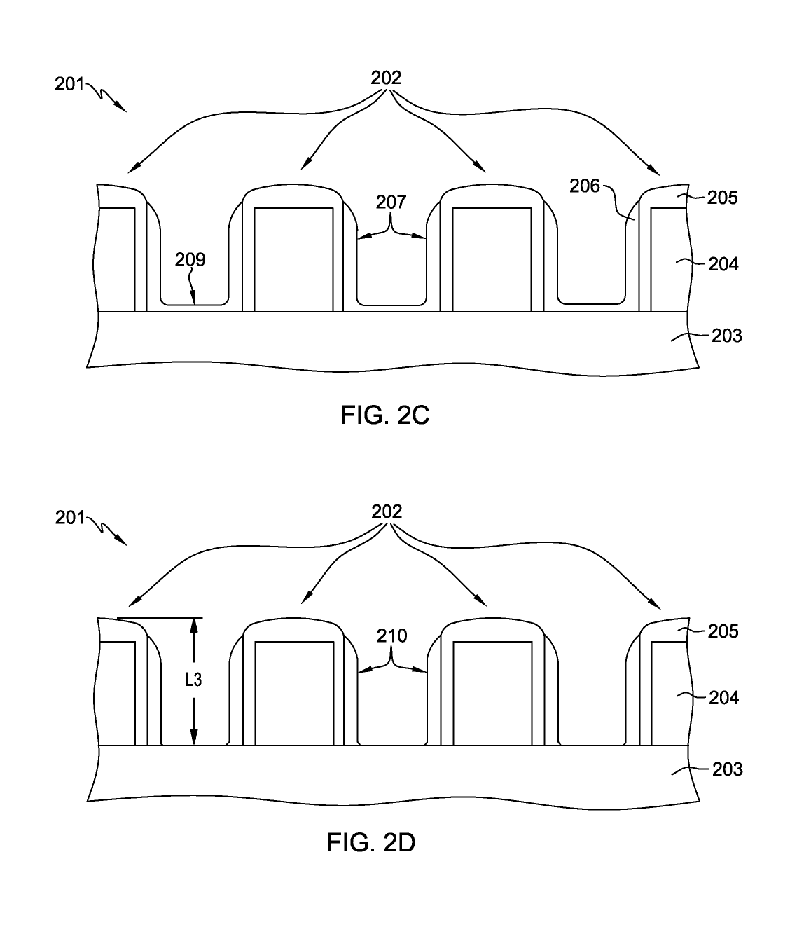

An embodiment of the current invention is shown in FIGS. 2A-2D. FIG. 2A is a partial semiconductor structure 201 during an intermediate fabrication step. Gate structures 202 have been formed on substrate 203. Substrate 203 may be (in one example) a bulk semiconductor material such as a bulk silicon wafer. As another example, substrate 203 may be or include any silicon-containing substrate including, but not limited to, single crystal Si, polycrystalline Si, amorphous Si, Si-on-nothing (SON), Si-on-insulator (SOI), or Si-on-replacement insulator (SRI) substrates and the like, and may be n-type or p-type doped as desired for a particular application. In one example, substrate 203 may be, for instance, a wafer or substrate approximately 600-700 μm thick, or less. Gate structures 202 may be sacrificial gate structures, deposited on a substrate at one point of the fabrication process but later removed, to hold the place for a gate material such as a metal gate that is deposited later during fabrication.

Fins may extend from substrate 203, and may include one or more fins over which a gate structure 202 is conformally deposited. By way of example, fins may be formed by removing one or more portions of the substrate to create the fins from the same material as the substrate, such as, for example, a semiconductor or crystalline material. In one example, formation of fins may be achieved by patterning the substrate using any of various approaches, including: direct lithography; sidewall image transfer technique; extreme ultraviolet lithography (EUV); e-beam technique; litho-etch litho-etch; or litho-etch litho-freeze. Following patterning, material removal may be performed, for example, by any suitable etching process, such as an anisotropic dry etching process, for instance, reactive-ion-etching (RIE) in sulfur hexafluoride (SF₆). Although the following numbers are relative and the heights could vary, as one specific example, fins may have a height of about 40 nanometers, and a length of about one micrometer, several micrometers, or the diameter of the entire wafer, and the thickness of fins may be approximately 10 nm or less. In another example, the fins may be formed on the substrate, and the fins and the substrate may be different materials.

In the example shown in FIG. 2A, a gate structure is a gate stack of two layers: a gate material 204 and a protective layer 205. Gate material 204 may be any material well-known to skilled artisans to be a suitable gate material formed by standard deposition techniques such as polycrystalline silicon, and in one example may be approximately 30 nm wide. Not shown in FIG. 2A are other layers that may also be present in accordance with the present invention, such as a layer of dielectric material between the gate material and the substrate, and an interfacial layer between a dielectric layer and substrate 203. A layer of dielectric material between gate material 204 and substrate 203 may be a material having a high dielectric constant (high-k). However, it would be understood that a spacer such as an oxide spacer may be formed in accordance with the current invention in the absence of a protective layer 205, a layer of dielectric material between gate material 204 and substrate 203, or an interfacial layer between a dielectric layer and substrate 203.

Protective layer 205 may be any material well-known to skilled artisans to block or protect gate material or other underlying layers during subsequent processing steps, such as a nitride layer. Protective layer 205 may be silicon nitride, including carbon-doped silicon nitride. and may be conformally deposited by conventional deposition methods. Protective layer 205, or other layers of gate structure 202, may also include spacers that were formed before the formation of an oxide spacer in accordance with the current invention, and in one example may be from between 10 nm and 20 nm in thickness.

FIG. 2B is the same partial semiconductor substrate 201 after an additional layer 206 has been conformally deposited over the gate structures, including along the sidewalls of the gate structures 207 and adjacent to the gate structures across a surface of the substrate 208. Additional layer 206 is made of any material known to be suitable for forming a spacer, such as an oxide. An oxide may be silicon dioxide and may be deposited using any of a variety of deposition processes, including, for example, physical vapor deposition (PVD), atomic layer deposition (ALD), chemical vapor deposition (CVD), sputtering, or other processes, depending on the material composition of the layer. The deposition may conform to the substrate structure, including wrapping around fins of structure 203. In other embodiments, additional layer 206 may fill substantially all of the space between gate structures 202, or may be present only along the sidewalls of gate structures 207 and adjacent to the gate structures across a surface of the substrate 208 but absent from atop gate structures 202. In one example additional layer 206 may be conformally deposited and be from approximately 5 nm to 20 nm in thickness.

FIG. 2C is the same partial semiconductor structure 201 after part of additional layer 206 has been removed during a main etch step to define a spacer. A main etch step is an anisotropic etch process used to preferentially remove some portions of additional layer 206, while leaving part of additional layer 206 along sidewalls of a gate structures 207 which is where portions of additional layer 206 will remain to form spacers. For example, portions of additional layer from adjacent to the gate structures across a surface of the substrate 208 may be removed. If present, portions from atop gate structures 202 may also be removed. Because of the anisotropic nature of the main etch step, etching of additional layer 206 from atop gate structures 202 and from adjacent to the gate structures across a surface of the substrate 208 substantially predominates over etching from along the sidewalls 207 of gate structures 202, resulting in the defining of spacers.

If additional layer 206 is an oxide, an anisotropic etch step known to be suitable for etching an oxide layer and defining an oxide spacer may be used. The anisotropic etch step may use any chemistry and process suitable for removing portions of additional layer 206 from substrate 203, such as a plasma etch step using CHF₃, CF₄, CH₂F₂, or CH₃F. After a main etch step, some residual portion 209 of additional layer 206 adjacent to the gate structures across a surface of the substrate may still be present, although thinner than that portion was before the main etch step 208 (FIG. 2B). Residual portion 209 may be 5 nm thick, 1 nm thick, or less, and may possess slight heterogeneities in thickness or discontinuities; in places, some portion of the underlying substrate 203 may be uncovered by residual portion 209. In general, where residual portion 209 is between two gate structures 202, the closer together the gate structures 202 are to each other, the thicker residual portion 209 may be.

An over etch step is performed after a main etch step. In accordance with the current invention, an over etch step is an isotropic etch process to remove residual portion 209 adjacent to the gate structures across a surface of the substrate 203 that remains following a main etch step. The isotropic over etch step may also remove any residual portion of additional layer 206 that remained atop gate structures 202 after a main etch step. The isotropic over etch process is highly selective for the material of additional layer 206 compared to substrate 203, such that gouging of substrate 203 during over etch is reduced and preferentially negligible or nonexistent. If additional layer 206 is an oxide, an isotropic over etch step, in accordance with the current invention, may be any isotropic etch process using any isotropic etch chemistry that is known to be selective for the oxide compared to the substrate 203. For example, in accordance with the current invention, an isotropic over etch process may be an isotropic CERTAS® etch process or an isotropic SICONI® etch process, may use HF, NH₃, NF₃, or a combination thereof, and may use a remote plasma isotropic etch process.

FIG. 2D is the same partial semiconductor substrate 201 after the isotropic over etch step has been completed. The portions of additional layer 206 that remained along sidewalls of gate structures 202 are now spacers 210. Residual portions 209 (FIG. 2C) of additional layer 206 from adjacent to the gate structures 202 across a surface of the substrate 203 have been removed. Because the isotropic over etch process is selective for additional layer 206, substrate gouging is substantially avoided. As a result, distance from the top of a gate structure 202 to the surface of substrate 203 before spacer formation, indicated as L3 in FIG. 2A, is substantially the same as the distance from the top of gate structure 202 to the surface of substrate 203 after the over etch step, indicated as L3 in FIG. 2D. In other embodiments, although some substrate gouging may occur during a main etch step, using an isotropic over etch step in accordance with the current invention substantially avoids increasing such gouging. This substantial reduction or avoidance of gouging of substrate 203 beneficially improves the functionality of a resulting FET. For example, current leakage may be less than results from a conventional FET fabrication process.

Although an isotropic etch step may remove some of an additional layer 206 along sidewalls 207, it may be stopped after residual portions 209 of additional layer 206 adjacent to the gate structures across a surface of the substrate are removed, while leaving part of additional layer 206 along sidewalls of a gate structures 207 to form spacers 210. The temporal and other parameters used in performing an anisotropic main etch step and an isotropic over etch step will vary depending on conditions such as the desired spacer material, the desired spacer size, the starting thickness of additional layer 206, the desired and actual thickness of residual portion 209 of additional layer 206 adjacent to the gate structures across a surface of the substrate after a main etch step, and the type of isotropic over etch process used. Accounting for such variables in determining the parameters to adopt for steps involved in FET fabrication is standard practice, and skilled artisans would be capable of modifying relevant processes to adjust for such factors as a routine matter in order to practice the invented method. As non-limiting examples, an anisotropic main etch step may be from between approximately 15 seconds to 50 seconds in duration and an isotropic over etch step may from between approximately 10 seconds to 40 seconds in duration, in accordance with the current invention.

An isotropic over etch step may be used in accordance with the current invention for fabrication of p-type and n-type FETs, and in processes known in the industry as gate-first and gate-last, such as where a gate electrode is formed before or after source and drain dopants are activated by an annealing step, respectively.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. An embodiment was chosen and described in order to explain principles of one or more aspects of the invention and practical application, and to enable others of ordinary skill in the art to understand one or more aspects of the invention for various embodiments with various modifications as are suited to a particular use contemplated.

1. A method of manufacturing a semiconductor device comprising:
forming a gate structure on a substrate, wherein the gate structure comprises sidewalls;
depositing an oxide layer along the sidewalls of the gate structure and on the substrate;
removing some of the oxide layer to define at least one oxide spacer along at least one sidewall of the gate structure; and
performing an isotropic etch process to remove a residual portion of the oxide layer from adjacent the at least one oxide spacer.

2. The method of claim 1, wherein the isotropic etch process comprises using HF gas, NH₃ gas, NF₃ gas, or any combination thereof.

3. The method of claim 1, wherein the isotropic etch process comprises a remote plasma etch process.

4. The method of claim 1, wherein removing some of the oxide layer to define at least on oxide spacer comprises an anisotropic etch process.

5. The method of claim 4, wherein the isotropic etch process comprises using HF gas, NH₃ gas, NF₃ gas, or any combination thereof.

6. The method of claim 4, wherein the isotropic etch process comprises a remote plasma etch process.

7. The method of claim 4, wherein the anisotropic etch process comprises using CHF₃ gas, CF₄ gas, CH₂F₂ gas, or CH₃F gas.

8. The method of claim 7, wherein the isotropic etch process comprises using HF gas, NH₃ gas, NF₃ gas, or any combination thereof.

9. The method of claim 7, wherein the isotropic etch process comprises a remote plasma etch process.

10. The method of claim 1 wherein the substrate comprises a silicon-containing material.

11. The method of claim 10 wherein the silicon-containing material comprises bulk material, single crystal Si, polycrystalline Si, amorphous Si, Si-on-nothing, Si-on-insulator, or Si-on-replacement insulator.

12. The method of claim 1 wherein the oxide comprises silicon dioxide.

13. The method of claim 11 wherein the oxide comprises silicon dioxide.

14. The method of claim 12, wherein the isotropic etch process comprises using HF gas, NH₃ gas, NF₃ gas, or any combination thereof.

15. The method of claim 12, wherein the isotropic etch process comprises a remote plasma etch process.

16. The method of claim 12, wherein removing some of the oxide layer to define at least on oxide spacer comprises an anisotropic etch process.

17. The method of claim 12, wherein the anisotropic etch process comprises using CHF₃ gas, CF₄ gas, CH₂F₂ gas, or CH₃F gas.

18. A method of manufacturing a semiconductor device comprising:
forming a gate structure on a substrate wherein the gate structure comprises sidewalls and the substrate comprises bulk material, single crystal Si, polycrystalline Si, amorphous Si, Si-on-nothing, Si-on-insulator, or Si-on-replacement insulator;
depositing an oxide layer along the sidewalls of the gate structure and on the substrate, wherein the oxide comprises silicon dioxide;
performing an anisotropic etch process to remove some of the oxide layer to define at least one oxide spacer along at least one sidewall of the gate structure; and
performing an isotropic etch process to remove a residual portion of the oxide layer from adjacent the at least one oxide spacer.

19. The method of claim 18, wherein the isotropic etch process comprises using HF gas, NH₃ gas, NF₃ gas, or any combination thereof.

20. The method of claim 18, wherein the isotropic etch process comprises a remote plasma etch process.
